(19) United States
(12) Patent Application Publication
(10) Pub. No.: US 2021/0273155 A1
(43) Pub. Date: Sep. 2, 2021

(54) MTJ STACK WITH SELF-ORDERING TOP MAGNETIC FREE LAYER WITH TETRAGONAL CRYSTALLINE SYMMETRY

(71) Applicant: International Business Machines Corporation, Armonk, NY (US)

(72) Inventor: Matthias Georg Gottwald, New Rochelle, NY (US)

(21) Appl. No.: 16/804,950

(22) Filed: Feb. 28, 2020

(51) Int. Cl. H01L 43/02; H01L 27/22; H01L 43/10

(52) U.S. Cl. CPC H01L 43/02; H01L 43/10; H01L 27/222

(57) ABSTRACT

A bottom pinned magnetic tunnel junction (MTJ) stack containing a top magnetic free layer having a high perpendicular magnetic anisotropy field is provided which can be used as an element/component of a spin-transfer torque (STT) MRAM device. The top magnetic free layer is composed of an ordered aluminum-manganese-germanium-containing alloy having a tetragonal crystalline symmetry. The top magnetic free layer is formed directly on a tunnel barrier layer of the bottom pinned MTJ stack without the need of a specialized metallic seed layer.

### BACKGROUND

The present application relates to magnetoresistive random access memory (MRAM). More particularly, the present application relates to a bottom pinned magnetic tunnel junction (MTJ) stack including a top magnetic free layer having a high perpendicular magnetic anisotropy field which can be used in a spin-transfer torque (STT) MRAM device.

STT MRAM devices use a 2-terminal device which includes a MTJ stack that contains a magnetic pinned (reference) layer, a tunnel barrier layer and a magnetic free layer. MTJ stacks can be classified into two types. The first type of MTJ stack is a bottom pinned MTJ stack and the second type of MTJ stack is a top pinned MTJ stack. A typical bottom pinned MTJ stack, which is illustrated in FIG. 1, includes a magnetic pinned (or reference) layer 10, a tunnel barrier layer 12, and a magnetic free layer 14. A MTJ capping layer 16 is typically present on the magnetic free layer 14 of the bottom pinned MTJ stack shown in FIG. 1. In a typical top pinned MTJ stack, as is shown in FIG. 2, the magnetic free layer 14 is located beneath the tunnel barrier layer 12, and the magnetic pinned layer 10 is located above the tunnel barrier layer 12; a MTJ capping layer 16 is typically present on the magnetic pinned layer 10 of the top pinned MTJ stack shown in FIG. 2. In FIGS. 1 and 2, the arrow within the magnetic pinned layer 10 shows a possible orientation of that layer and the double headed arrow in the magnetic free layer 14 illustrates that the orientation in that layer can be switched.

In the MTJ stacks shown in FIGS. 1 and 2, the magnetization of the magnetic pinned layer 10 is fixed in one direction (say pointing up) and a current passed down through the junction makes the magnetic free layer 14 parallel to the magnetic pinned layer 10, while a current passed up through the junction makes the magnetic free layer 14 anti-parallel to the magnetic pinned layer 10. A smaller current (of either polarity) is used to read the resistance of the device, which depends on the relative orientations of the magnetizations of the magnetic free layer 14 and the magnetic pinned layer 10. The resistance is typically higher when the magnetizations are anti-parallel, and lower when they are parallel (though this can be reversed, depending on the material).

Various types of magnetic materials can be used in providing magnetic free layers of a MTJ stack. For example, the magnetic free layer can be composed of at least one magnetic material (such as, for example, a cobalt-iron-boron alloy) with a magnetization that can be changed in orientation relative to the magnetization orientation of the magnetic pinned layer. Such a magnetic material may be used as the magnetic free layer in either a bottom pinned MTJ stack, as shown in FIG. 1, or a top pinned MTJ stack, as shown in FIG. 2. In another example, the magnetic free layer can be composed of a Heusler or half Heusler based alloy such as, for example, a manganese-germanium (Mn—Ge) alloy or a manganese-gallium (Mn—Ga) alloy. By definition Heusler or half Heusler based alloy have a specific crystalline symmetry and order. Magnetic properties of the Heusler or half Heusler based alloy strongly depend, not only on the composition of elements, but on their crystalline arrangement/order. This is different from, e.g., typical CoFe alloys where the positions of Fe and Co atoms can be swapped in the crystalline lattice without modifying the magnetic properties. Achieving such crystalline ordering for Heusler or half Heusler based alloys creates a significant additional difficulty for materials engineering.

In cases in which a Heusler or half Heusler based alloy is used as the magnetic free layer of a MTJ stack, a specialized metallic seed layer (a so-called chemical templating layer) such as, for example, an aluminum-cobalt (Al—Co) alloy seed layer or an aluminum-iridium (Al—Ir) alloy seed layer with Cs—Cl structure, is needed to promote crystalline ordering of the Heusler or half Heusler based alloy. Due to the strict metallic seed layer requirement, Heusler or half Heusler based alloys have only been traditionally used as a bottom free layer in a top pinned MTJ stack.

Ordered magnetic alloys, such as Heusler or half Heusler based alloys, provide a scalability advantage over traditional cobalt-iron-boron alloys due to their bulk anisotropy properties. This means, that even at a small size, the retention properties of ordered magnetic alloys such as, for example, Heusler or half Heusler based alloys, can be improved by thickening the magnetic free layer; this is not possible for interface anisotropy governed by cobalt-iron-boron alloys.

### SUMMARY

A bottom pinned MTJ stack containing a top magnetic free layer having a high perpendicular magnetic anisotropy field is provided which can be used as an element/component of a STT MRAM device. The top magnetic free layer is composed of an ordered aluminum-manganese-germanium-containing alloy having a tetragonal crystalline symmetry. The ordered aluminum-manganese-germanium-containing alloy that provides the top magnetic free layer of the present application is formed directly on a tunnel barrier layer of the bottom pinned MTJ stack without the need of a specialized metallic seed layer.

In one aspect of the present application, a bottom pinned MTJ stack is provided. In one embodiment, the bottom pinned MTJ stack includes a tunnel barrier layer located on a magnetic pinned layer, and a magnetic free layer located on the tunnel barrier layer, wherein the magnetic free layer is composed of an ordered aluminum-manganese-germanium-containing alloy having a tetragonal crystalline symmetry.

In another aspect of the present application, a STT MRAM device is provided. In one embodiment, the STT MRAM device includes a bottom pinned MTJ stack located on a surface of a bottom electrode. In one embodiment, the bottom pinned MTJ stack structure includes a tunnel barrier layer located on a magnetic pinned layer, and a magnetic free layer located on the tunnel barrier layer, wherein the magnetic free layer is composed of an ordered aluminum-manganese-germanium-containing alloy having a tetragonal crystalline symmetry.

### BRIEF DESCRIPTION OF THE DRAWINGS

FIG. 1 is a cross sectional view of a prior art bottom pinned MTJ stack which includes, from bottom to top, a magnetic pinned (or reference) layer, a tunnel barrier layer, and a magnetic free layer.

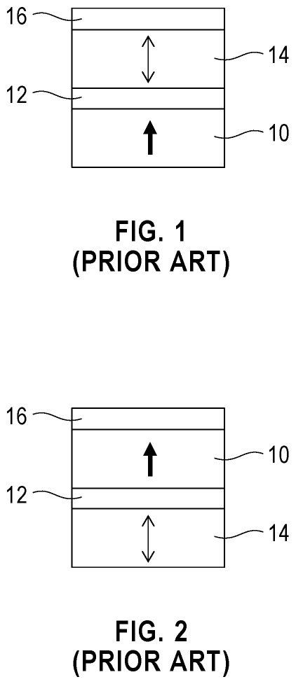

FIG. 2 is a cross sectional view of a prior art top pinned MTJ stack which includes, from bottom to top, a magnetic free layer, a tunnel barrier layer, and a magnetic pinned (or reference) free layer.

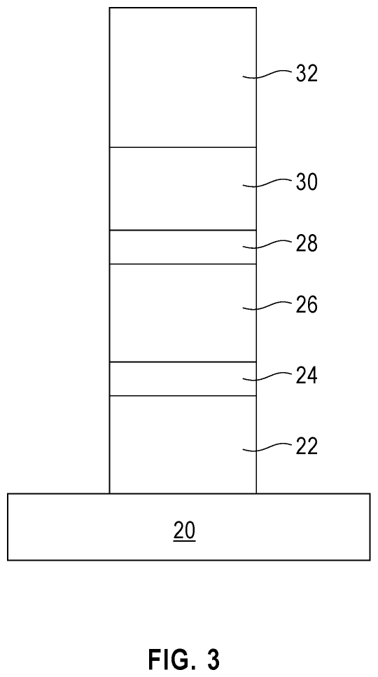

FIG. 3 is a cross sectional view of a bottom pinned MTJ stack in accordance with one embodiment of the present application and located on a bottom electrode, wherein the bottom pinned MTJ stack includes are least a tunnel barrier layer located on a magnetic pinned layer, and a magnetic free layer located on the tunnel barrier layer, wherein the magnetic free layer is composed of an ordered aluminum-manganese-germanium-containing alloy having a tetragonal crystalline symmetry.

FIGS. 4A, 4B and 4C are graphs showing the perpendicular blanket film hysteresis loops for various bottom pinned MTJ stacks in accordance with the present application and having different thicknesses for the ordered aluminum-manganese-germanium-containing alloy magnetic free layer.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

The present application provides a bottom pinned MTJ stack in which a top magnetic free layer having a high perpendicular magnetic anisotropy field is used. Notably, the top magnetic free layer in the bottom pinned MTJ stack of the present application is composed of an ordered aluminum-manganese-germanium-containing alloy which has a tetragonal crystalline symmetry. The top magnetic free layer is formed directly on a tunnel barrier layer of the bottom pinned MTJ stack without the need of a specialized metallic seed layer. Thus, a direct interface between the ordered aluminum-manganese-germanium-containing alloy and the underlying tunnel barrier is obtained in the bottom pinned MTJ stack of the present application.

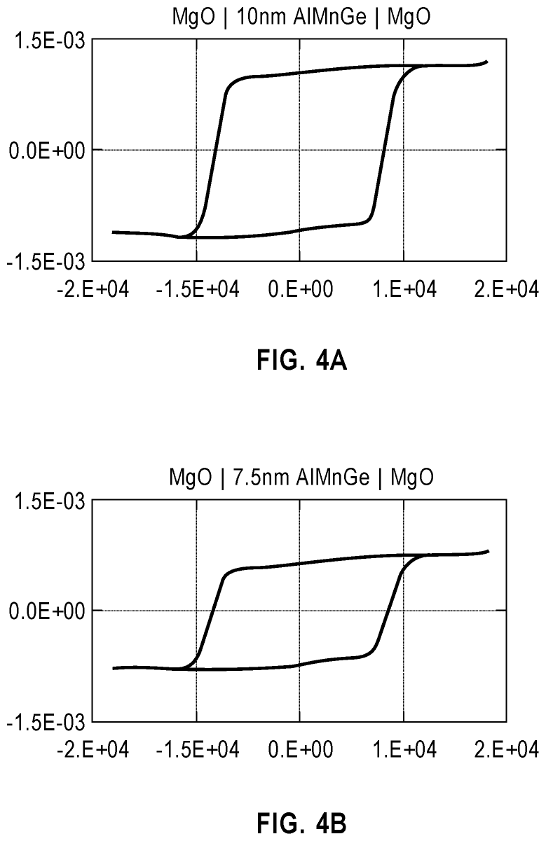

Referring now to FIG. 3, there is illustrated a bottom pinned MTJ stack in accordance with one embodiment of the present application. As is shown, the bottom pinned MTJ stack is located on a bottom electrode 20; collectively the bottom pinned MTJ stack and the bottom electrode 20 illustrated in FIG. 3 provide elements/components of a STT MRAM device. In the illustrated embodiment shown in FIG. 3, the bottom pinned MTJ stack includes, from bottom to top, a magnetic pinned layer 22, a tunnel barrier layer 24, and a magnetic free layer 26 composed of an ordered aluminum-manganese-germanium-containing alloy having a tetragonal crystalline symmetry. The bottom pinned MTJ stack can also include a MTJ capping layer 28, an etch stop layer 30 and a hard mask 32.

As is shown in FIG. 3, the magnetic free layer 26 forms a direct interface with the tunnel barrier layer 24; no metallic seed layer is located between the magnetic free layer 26 and the underlying tunnel barrier layer 24. The structure shown in FIG. 3 will now be described in greater detail. The bottom electrode 20 of the structure shown in FIG. 3 is typically located on a surface of an electrically conductive structure (not shown). The electrically conductive structure is embedded in an interconnect dielectric material layer (also not shown). Another interconnect dielectric material layer (not shown) may embed the MTJ stack illustrated in FIG. 3. Another electrically conductive structure (not shown) can contact a surface of the hard mask 32, which typically functions as a top electrode of the MRAM device.

The bottom electrode 20 may be composed of an electrically conductive material such as, for example, an electrically conductive metal, an electrically conductive metal alloy, or an electrically conductive metal nitride. Examples of electrically conductive metals that can be used to provide the bottom electrode 20 include, but are not limited to, copper (Cu), ruthenium (Ru), cobalt (Co), rhodium (Rh), tungsten (W), aluminum (Al), tantalum (Ta) or titanium (Ti). An example of electrically conductive metal alloy that can be used to provide the bottom electrode 20 includes, but is not limited to, Cu—Al, and an example of electrically conductive metal nitride that can be used to provide the bottom electrode 20 includes, but is not limited to, TaN or TiN. The bottom electrode 20 can be formed utilizing techniques well known to those skilled in the art. The conductive material that provides the bottom electrode 20 can be formed utilizing a deposition process such as, for example, chemical vapor deposition (CVD), plasma enhanced chemical vapor deposition (PECVD), sputtering or plating. The bottom electrode 20 can have a thickness from 10 nm to 200 nm; although other thicknesses are possible and can be used as the thickness of the bottom electrode 20. The bottom electrode 20 can be formed on a recessed surface or a non-recessed surface of the electrically conductive structure (not shown).

The magnetic pinned layer 22 that is employed in the present application has a fixed magnetization; the magnetic pinned layer 22 can also be referred to as a magnetic reference layer. The magnetic pinned layer 22 can be composed of a metal or metal alloy that includes one or more metals exhibiting high spin polarization. In alternative embodiments, exemplary metals for the formation of the magnetic pinned layer 22 include iron, nickel, cobalt, chromium, boron, and manganese. Exemplary metal alloys may include the metals exemplified above (i.e., iron, nickel, cobalt, chromium, boron, and manganese). In another embodiment, the magnetic pinned layer 22 may be a multilayer arrangement having (1) a high spin polarization region formed from of a metal and/or metal alloy using the metals mentioned above (i.e., iron, nickel, cobalt, chromium, boron, and manganese), and (2) a region constructed of a material or materials that exhibit strong perpendicular magnetic anisotropy (strong PMA). Exemplary materials with strong PMA that may be used include a metal such as cobalt, nickel, platinum, palladium, iridium, or ruthenium, and may be arranged as alternating layers. The strong PMA region may also include alloys that exhibit strong PMA, with exemplary alloys including cobalt-iron-terbium, cobalt-iron-gadolinium, cobalt-chromium-platinum, cobalt-platinum, cobalt-palladium, iron-platinum, and/or iron-palladium. The alloys may be arranged as alternating layers. In one embodiment, combinations of these materials and regions may also be employed. The magnetic pinned layer 22 that can be employed in the present application can have a thickness from 3 nm to 20 nm; although other thicknesses for the magnetic pinned layer 22 can be used.

The tunnel barrier layer 24 is composed of an insulator material and is formed at such a thickness as to provide an appropriate tunneling resistance. Exemplary materials for the tunnel barrier layer 24 include magnesium oxide, aluminum oxide, and titanium oxide, or materials of higher electrical tunnel conductance, such as semiconductors or low-bandgap insulators. In one embodiment, magnesium oxide is used as the material that provides the tunnel barrier layer 24. The thickness of tunnel barrier layer 24 can be from 0.5 nm to 1.5 nm; although other thicknesses for the tunnel barrier layer 24 can be used as long as the selected thickness provides a desired tunnel barrier resistance.

The magnetic free layer 26 that is employed in the present application is an ordered aluminum-manganese-germanium-containing alloy (i.e., Al—Mn—Ge) having a tetragonal crystalline symmetry. The term “tetragonal crystalline symmetry” denotes a crystal structure having a unit cell containing three axes, two of which are of the same length and are at right angles to each other, and the third axis is perpendicular to the other two axes. Tetragonal crystalline lattices result from stretching a cubic lattice along one of its lattice vectors, so that the cube becomes a rectangular prim with a square base (x by x) and a height (y, which is different from x).

The manganese-germanium-containing (i.e., Al—Mn—Ge) alloy that can be used as the magnetic free layer 26 typically has an atomic ratio of 1:1:1 between the Al, Mn and Ge. In some embodiments, the manganese-germanium-containing (i.e., Al—Mn—Ge) alloy that can be used as the magnetic free layer 26 can have an atomic ratio that deviates 10% or less from the 1:1:1 ratio mentioned above. In some embodiments, up to 20 atomic percent of the total manganese content of the ordered aluminum-manganese-germanium-containing alloy is replaced with chromium (Cr); an ordered Cr—Mn—Al—Ge alloy is provided which also has the tetragonal crystalline symmetry. The ordered Cr—Mn—Al—Ge alloy can also be used as the magnetic free layer 26. In one embodiment, from 1 to 20 atomic percent of the total manganese content of the ordered aluminum-manganese-germanium-containing alloy is replaced with Cr.

The magnetic free layer 26 of the present application can have a thickness from 3 nm to 10 nm. The magnetic free layer 26 of the present application which includes the ordered manganese-germanium-containing (i.e., Al—Mn—Ge) alloy, with or without Cr replacement, has a magnetic moment area from 0.035 milli-emu/cm² to 0.15 milli-emu/cm². Magnetic moment area was determined by magnetometry using a vibrating sample magnetometer (VSM).

The magnetic free layer 26 of the present application which includes the ordered manganese-germanium-containing (i.e., Al—Mn—Ge) alloy, with or without Cr replacement, typically has a perpendicular magnetic anisotropy field that is greater than 2 Tesla. In some embodiments, the perpendicular magnetic anisotropy field of the magnetic free layer 26 of the present application can be from 0.5 Tesla to 5 Tesla. Magnetic anisotropy field was determined by magnetometry using a vibrating sample magnetometer (VSM).

The MTJ capping layer 28 is present on the magnetic free layer 26. The MTJ capping layer 28 is preferentially composed of magnesium oxide (MgO). Other materials for the MTJ capping layer 28 include aluminum oxide (Al₂O₃), calcium oxide (CaO), tantalum oxide (Ta₂O₅), niobium oxide (Nb₂O₅) or ternary oxides such as, for example, Mg_{y}Ti_{1-y}pₓ. The MTJ capping layer 28 can have a thickness from 0.3 nm to 2 nm; other thicknesses are possible and can be used in the present application as the thickness of the MTJ capping layer 28.

The etch stop layer 30 is composed of a metal such as, for example, ruthenium (Ru) or iridium (Ir) that has a higher etch rate compared to the hard mask 32 which prevents the magnetic pinned layer 22, the tunnel barrier layer 24 and the magnetic free layer 26 from being exposed to the etchant materials used to pattern the hard mask 32. The etch stop layer 30 can have a thickness from 5.0 nm to 30 nm; although other thicknesses for the etch stop layer 30 can be used in the present application.

The hard mask 32 can be composed of a metal nitride such as, for example, tantalum nitride (TaN) or titanium nitride (TiN) or a metal such as, for example, titanium (Ti) or tantalum (Ta), which is compositionally different from the material used to provide the etch stop layer 30. In some embodiments, the hard mask 32 can be employed as a top electrode of the STT MRAM device. In other embodiment, a separate top electrode (composed of one of the electrically conductive materials mentioned above for the bottom electrode 20) can be formed on the hard mask 32. The hard mask 32 can have a thickness from 50 nm to 1500 nm; although other thicknesses for the hard mask 32 can be used in the present application.

The MTJ stack shown in FIG. 3 can be formed by deposition of the various material layers that provide the specific MTJ stack followed by a patterning process such as, for example, lithography and etching. The MTJ stack of the present application can have a critical dimension (CD) that is less than, or equal to, the critical dimension (CD) of the bottom electrode 20. The deposition of the various material layers that provide the specific MTJ stack can be performed in a same deposition tool or different deposition tools. For example, the magnetic pinned layer 22, the tunnel barrier layer 24, the magnetic free layer 26 can be deposited in a first deposition tool, and the MTJ capping layer 28, the etch stop layer 30 and the hard mask 32 can be deposited in a second deposition tool, which differs from the first deposition tool, and has deposition rates suitable for the deposition of those individual layers. The MTJ stack of the present application can be subjected to annealing process (i.e., a 400° C. anneal) after the formation of the same.

The various materials that provide the MTJ stack of the present application can be deposited by chemical vapor deposition (CVD), plasma enhanced chemical vapor deposition (PECVD), physical vapor deposition (PVD), atomic layer deposition (ALD) or sputtering. The various materials that provide the MTJ stack of the present application can be deposited utilizing the same or different deposition process. In one embodiment of the present application, the magnetic free layer 26 described above can be formed using one or more stoichiometrically adjusted targets by sputtering or co-sputtering. In some embodiments of the present application, the tunnel barrier layer 24 and/or the MTJ capping layer can be formed by sputtering MgO from a stoichiometeric MgO target, or by oxidation of a grown Mg layer, or by utilizing a combination of both.

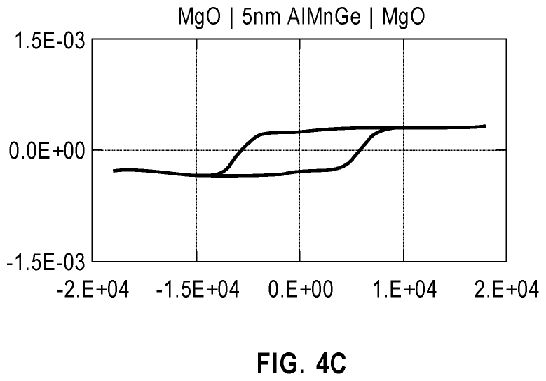

Referring now to FIGS. 4A, 4B and 4C, there are shown actual perpendicular blanket film hysteresis loops for various bottom pinned MTJ stacks in accordance with the present application and having different thicknesses for the aluminum-manganese-germanium-containing alloy magnetic free layer; in FIG. 4A, a 10 nm Al—Mn—Ge alloy was used, in FIG. 4B, a 7.5 nm Al—Mn—Ge alloy was used, and in FIG. 4C, a 5 nm Al—Mn—Ge alloy was used. Each bottom pinned MTJ stack used in generating the data shown in FIGS. 4A, 4B, and 4C included from, bottom to top, an amorphous TaN/Ta metallic seed layer having a thickness of 20 nm, 0.3 nm thick Co—Fe—B alloy pinned layer, a 1.5 nm thick MgO tunnel barrier, a magnetic free layer composed of an Al—Mn—Ge alloy having the different thicknesses identified above, and a 1. 2 nm thick MgO capping layer. The perpendicular blanket film hysteresis loops were generated by magnetometry using a vibrating sample magnetometer (VSM). Alloys like AlMnGe only show ferromagnetic order and perpendicular magnetic anisotropy when having a tetragonal crystalline with the long axis of the tetragonal crystal perpendicular to the surface; see, for example, the publication to Rie Y. Umetsu et al. entitled “Substitution Effects of Cr or Fe on the Curie Temperature for Mn-based Layered Compounds MNAlGe and MnGaGe with Cu₂Sb-Type Structure”, IEEE Transactions on Magnetics, Vol. 50, No. 11, November 2014. Therefore, the magnetometry data in FIGS. 4A-4B evidences that AlMnGe grown on a typical MgO tunnel barrier which is state of the art has a high level of crystalline order as described in the literature. FIG. 4C shows that this is even true for a film as thin as 5 nm. This shows that AlMnGe on top of a typical MgO barrier can be scaled to thicknesses and moment per area densities which are relevant to STT MRAM.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A bottom pinned magnetic tunnel junction (MTJ) stack comprising:
a tunnel barrier layer located on a magnetic pinned layer; and
a magnetic free layer located on the tunnel barrier layer, wherein the magnetic free layer is composed of an ordered aluminum-manganese-germanium-containing alloy having a tetragonal crystalline symmetry.

2. The bottom pinned MTJ stack of claim 1, wherein up to 20 atomic percent of the total manganese content of the ordered aluminum-manganese-germanium-containing alloy is replaced with chromium.

3. The bottom pinned MTJ stack of claim 1, further comprising a MTJ capping layer located on the magnetic free layer.

4. The bottom pinned MTJ stack of claim 3, further comprising an etch stop layer located on the MTJ capping layer and a hard mask located on the etch stop layer.

5. The bottom pinned MTJ stack of claim 4, wherein the tunnel barrier layer is composed of magnesium oxide, the MTJ capping layer is composed of magnesium oxide, the hard mask is composed of ruthenium and the hard mask is composed of tantalum nitride.

6. The bottom pinned MTJ stack of claim 1, wherein the magnetic free layer has a thickness from 3 nm to 10 nm.

7. The bottom pinned MTJ stack of claim 1, wherein the magnetic free layer has a magnetic moment area from 0.035 milli-emu/cm² to 0.15 milli-emu/cm².

8. The bottom pinned MTJ stack of claim 1, wherein the magnetic free layer has a perpendicular magnetic anisotropy field that is greater than 2 Tesla.

9. The bottom pinned MTJ stack of claim 1, wherein the magnetic reference layer is composed of a cobalt-iron-boron alloy.

10. A spin-transfer torque magnetoresistive random access memory (STT MRAM) device comprising:
a bottom pinned magnetic tunnel junction (MTJ) stack located on a bottom electrode, wherein the bottom pinned MTJ stack comprises a tunnel barrier layer located on a magnetic pinned layer, and a magnetic free layer located on the tunnel barrier layer, wherein the magnetic free layer is composed of an ordered aluminum-manganese-germanium-containing alloy having a tetragonal crystalline symmetry.

11. The STT MRAM device of claim 10, wherein up to 20 atomic percent of the total manganese content of the ordered aluminum-manganese-germanium-containing alloy is replaced with chromium.

12. The STT MRAM device of claim 10, further comprising a MTJ capping layer located on the magnetic free layer.

13. The STT MRAM device of claim 12, further comprising an etch stop layer located on the MTJ capping layer and a hard mask located on the etch stop layer.

14. The STT MRAM device of claim 13, wherein the tunnel barrier layer is composed of magnesium oxide, the MTJ capping layer is composed of magnesium oxide, the hard mask is composed of ruthenium and the hard mask is composed of tantalum nitride.

15. The STT MRAM device of claim 10, wherein the magnetic free layer has a thickness from 3 nm to 10 nm.

16. The STT MRAM device of claim 10, wherein the magnetic free layer has a magnetic moment area from 0.035 milli-emu/cm² to 0.15 milli-emu/cm².

17. The STT MRAM device of claim 10, wherein the magnetic free layer has a perpendicular magnetic anisotropy field that is greater than 2 Tesla.

18. The STT MRAM device of claim 1, wherein the magnetic reference layer is composed of a cobalt-iron-boron alloy.

19. The STT MRAM device of claim 11, wherein the bottom electrode is composed of an electrically conductive metal, an electrically conductive metal alloy, or an electrically conductive metal nitride.

20. The STT MRAM device of claim 13, wherein the hard mask serves as a top electrode of the STT MRAM device.
